(19) United States
(12) Patent Application Publication
(10) Pub. No.: US 2025/0362608 A1
(43) Pub. Date: Nov. 27, 2025

(54) Resin Composition for Forming Resist Upper Layer Film, Pattern Forming Method, and Electronic Device Producing Method

(71) Applicant: Central Glass Company, Limited, Ube-shi, Yamaguchi (JP)

(72) Inventors: Takashi MASUBUCHI, Chiyoda-ku, Tokyo (JP); Takashi AOKI, Chiyoda-ku, Tokyo (JP); Fumihiro AMEMIYA, Chiyoda-ku, Tokyo (JP)

(21) Appl. No.: 18/874,895

(22) PCT Filed: Jun. 12, 2023
(86) PCT No.: PCT/JP2023/021690

§ 371 Date: Dec. 13, 2024

(30) Foreign Application Priority Data
Jun. 14, 2022 (JP) 2022-095902

(51) Int. Cl. G03F 7/11; G03F 7/00; G03F 7/075

(52) U.S. Cl. CPC G03F 7/11; G03F 7/0752; G03F 7/70033

(57) ABSTRACT

Provided is a resin composition for forming a resist upper layer film including one or more sensitizing elements selected from the group consisting of Ge, Mo, Hf, Zr, Ta, W, Cr, Co, Fe, Pt, Sn, and Sb, in which an amount of the sensitizing element in non-volatile components is 5 at % or more. Also provided is a method for forming a pattern including a step of forming a photoresist film over a substrate, a step of forming a resist upper layer film over the photoresist film using the resin composition for forming a resist upper layer film, an exposing step of exposing the photoresist film and the resist upper layer film, and a step of removing at least a part of the photoresist film using a developer.

### TECHNICAL FIELD

The present invention relates to a resin composition for forming a resist upper layer film, a method for forming a pattern, and a method for producing an electronic device. More specifically, the present invention relates to a resin composition for forming a resist upper layer film which is preferably applied to an EUV lithography process, a method for forming a pattern using the composition, and a method for producing an electronic device.

### BACKGROUND ART

In the field of semiconductor lithography, development is ongoing as to EUV lithography using extreme ultraviolet (EUV) light as an exposure light source.

A fundamental problem in EUV lithography is to improve sensitivity. This is because the output of EUV light sources is still low as of 2022.

In order to compensate for the low output of EUV light sources, a method for improving sensitivity by improving a photoresist or a material around the photoresist is considered.

For example, Patent Document 1 discloses an idea of forming a metal-containing top coat over a resist layer in order to improve sensitivity in EUV lithography. However, the idea described in Patent Document 1 is not accompanied by specific examples (actual preparation of a top coat composition, and the like).

### RELATED DOCUMENT

### Patent Document

[Patent Document 1] PCT Japanese Translation Patent Publication No 2021-508071

### SUMMARY OF THE INVENTION

### Technical Problem

In view of the above-described fundamental problem in the EUV lithography, the present inventors have conducted investigations with an object of improving the sensitivity in the EUV lithography.

### Solution to Problem

As a result of the investigations, the present inventors have completed the invention provided below.

The present invention is as follows.

1. A resin composition for forming a resist upper layer film, the resin composition including:
one or more sensitizing elements selected from the group consisting of Ge, Mo, Hf, Zr, Ta, W, Cr, Co, Fe, Pt, Sn, and Sb,
in which an amount of the sensitizing element in non-volatile components is 5 at % or more.

2. The resin composition for forming a resist upper layer film according to 1., further including:
a resin containing the sensitizing element.

3. The resin composition for forming a resist upper layer film according to 2.,
in which the resin includes a polysiloxane-based resin containing the sensitizing element.

4. The resin composition for forming a resist upper layer film according to 2. or 3.,
in which the resin includes a polysiloxane-based resin in which a part of Si atoms of polysiloxane is replaced by the sensitizing element.

5. The resin composition for forming a resist upper layer film according to any one of 2. to 4.,
in which the resin is a resin having an alkali-soluble group.

6. The resin composition for forming a resist upper layer film according to 1. or 2., further including:
a resin; and
an additive component containing the sensitizing element as a component separate from the resin.

7. The resin composition for forming a resist upper layer film according to 6.,
in which the resin is a (meth) acrylic resin.

8. The resin composition for forming a resist upper layer film according to 6. or 7.,
in which the resin has an alkali-soluble group.

9. The resin composition for forming a resist upper layer film according to any one of 6. to 8.,
in which the additive component includes one or more selected from the group consisting of tetraethoxygermanium, silicotungstic acid, and bis [2-carboxyethylgermanium (IV)] sesquioxide.

10. The resin composition for forming a resist upper layer film according to any one of 1. to 9.,
in which the sensitizing element includes one or more selected from the group consisting of Ge, Mo, and W.

11. The resin composition for forming a resist upper layer film according to any one of 1. to 10., further including: an alcohol-based solvent.

12. The resin composition for forming a resist upper layer film according to any one of 1. to 11.,
in which the resin composition is non-photosensitive.

13. The resin composition for forming a resist upper layer film according to any one of 1. to 12.,
in which the resin composition is used in an EUV lithography process.

14. A method for forming a pattern, including:
a photoresist film forming step of forming a photoresist film over a substrate;
a resist upper layer film forming step of forming a resist upper layer film over the photoresist film using the resin composition for forming a resist upper layer film according to any one of 1. to 13.;
an exposing step of exposing the photoresist film and the resist upper layer film; and
a developing step of removing at least a part of the photoresist film using a developer.

15. The method for forming a pattern according to 14., in which the resist upper layer film is removed in the developing step.

16. The method for forming a pattern according to 14., further including:
a resist upper layer film removing step of removing the resist upper layer film, between the exposing step and the developing step.

17. The method for forming a pattern according to any one of 14. to 16.,
in which the exposing step is performed using EUV light.

18. The method for forming a pattern according to any one of 14. to 17.,
in which a thickness of the photoresist film is 30 nm or less.

19. A method for producing an electronic device, the method including:
the method for forming a pattern according to any one of 14. to 18.

### ADVANTAGEOUS EFFECTS OF INVENTION

According to the present invention, it is possible to improve sensitivity in EUV lithography.

### BRIEF DESCRIPTION OF THE DRAWINGS

FIG. 1 is a view for illustrating a photoresist film forming step in a method for forming a pattern.

FIG. 2 is a view for illustrating a resist upper layer film forming step in the method for forming a pattern.

FIG. 3 is a view for illustrating an exposing step in the method for forming a pattern.

FIG. 4 is a view for illustrating a developing step in the method for forming a pattern.

FIG. 5 is a view (website screenshot) for illustrating a procedure for calculating “EUV radiation absorption amount” in Examples.

### DESCRIPTION OF EMBODIMENTS

Hereinafter, embodiments of the present invention will be described in detail with reference to the drawings.

In all the drawings, the same constitutional components are denoted by the same reference signs, and description thereof will not be repeated as appropriate.

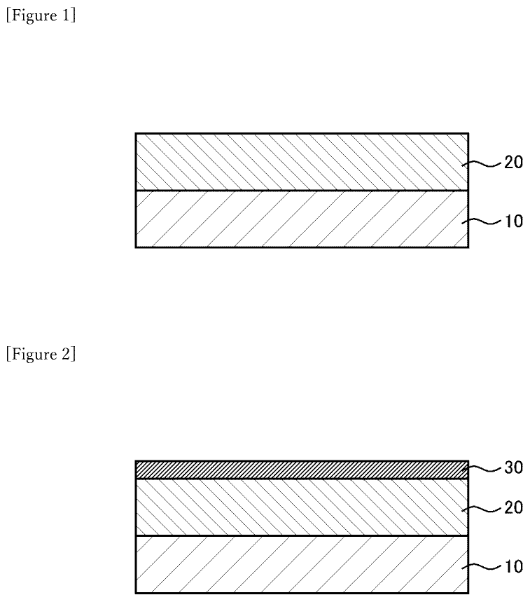

In order to avoid complication, (i) when a plurality of the same components are present in the same drawing, there may be a case where the reference numeral is given to only one component without giving the reference numeral to all the components; and (ii) in particular, in FIG. 2 and subsequent drawings, there may be a case where the reference numeral is not given again to the same components as those in FIG. 1.

All the drawings are merely illustrative. The shape or dimensional ratio of each member in the drawing does not necessarily correspond to those of an actual article.

In the present specification, “at %” represents % by atom, that is, a percentage based on the number of atoms.

In the present specification, the notation “X to Y” in the description of the numerical range indicates X or more and Y or less unless otherwise specified. For example, “1% to 5% by mass” means “1% by mass or more and 5% by mass or less”.

In a case where substitution or unsubstitution is not noted in regard to the notation of a group (atomic group) in the present specification, the group includes not only a group not having a substituent but also a group having a substituent. For example, the concept of an “alkyl group” includes not only an alkyl group not having a substituent (unsubstituted alkyl group) but also an alkyl group having a substituent (substituted alkyl group).

The expression “(meth) acryl” in the present specification represents a concept including both acryl and methacryl. The same applies to similar expressions such as “(meth) acrylate”. Unless otherwise specified, the term “organic group” as used in the present specification means an atomic group obtained by removing one or more hydrogen atoms from an organic compound. For example, a “monovalent organic group” refers to an atomic group obtained by removing one hydrogen atom from any organic compound.

In the present specification, the terms “non-volatile component” and “solid content” have the same meaning unless otherwise specified, and both terms mean a component other than a volatile component (mainly a solvent) in a composition or a solution.

The term “electronic device” in the present specification is used as a meaning including an element, a device, a final product, and the like, to which electronic engineering technology has been applied, such as a semiconductor chip, a semiconductor element, a printed circuit board, an electric circuit display device, an information communication terminal, a light emitting diode, a physical battery, and a chemical battery.

### Resin Composition for Forming Resist Upper Layer Film

A resin composition for forming a resist upper layer film according to the present embodiment contains one or more sensitizing elements selected from the group consisting of Ge, Mo, Hf, Zr, Ta, W, Cr, Co, Fe, Pt, Sn, and Sb.

The amount of the above-described sensitizing element in non-volatile components of the resin composition for forming a resist upper layer film according to the present embodiment is 5 at % or more.

According to a mechanism generally accepted in EUV lithography, in the EUV lithography, it is not EUV light itself but secondary electrons generated by the EUV light hitting elements act on the photoresist. In addition, the solubility of the photoresist in a developer is changed.

Based on the past knowledge, the above-listed sensitizing elements easily emit secondary electrons when EUV light is emitted. By performing EUV exposure after forming the upper layer film containing such a sensitizing element at a relatively high concentration of 5 at % or more in the non-volatile components on the photoresist film, secondary electrons are generated in the upper layer film. The secondary electrons are propagated to the photoresist film under the upper layer film, thereby changing the solubility of the photoresist film in a developer. That is, since not only the secondary electrons generated in the photoresist film, but also the secondary electrons propagated from the upper layer film to the photoresist film promote a change in the solubility of the photoresist film in a developer, the sensitivity is improved.

Incidentally, at least a part of the sensitizing element is not preferable as a “foreign matter” or “impurity” in semiconductor producing.

However, in the present embodiment, the sensitizing element is not necessarily included in the photoresist, and is present in the resist upper layer film “away from” the substrate.

Therefore, it is considered that the adverse effect due to the presence of the sensitizing element (5 at % or more in the non-volatile components) is reduced.

In addition, in the present embodiment, the photoresist film does not need to contain the sensitizing element. This is one of the advantages of the present embodiment. That is, an improvement in sensitivity can be promoted even when an existing photoresist is used without improving the photoresist itself.

The description of the resin composition for forming a resist upper layer film according to the present embodiment will be continued.

### (Amount (Concentration) of Sensitizing Element)

From the viewpoint of improving the sensitivity, the amount of the sensitizing element in the non-volatile components of the resin composition for forming a resist upper layer film according to the present embodiment is preferably 7 at % or more and more preferably 9 at % or more. On the other hand, from the viewpoint of balancing with other performance, the amount of the sensitizing element in the non-volatile components is preferably 20 at % or less, more preferably 18 at % or less, and still more preferably 15 at % or less.

In another expression, the amount of the sensitizing element in the non-volatile components is usually 5 to 20 at %, preferably 7 to 18 at % and more preferably 9 to 15 at %.

As described above, in the present embodiment, when the lithography process is executed, the sensitizing element is present in the resist upper layer film “away from” the substrate. Therefore, it is considered that even when a relatively large amount of the sensitizing element is present in the resist upper layer film, the adverse effect due to the presence is reduced.

Incidentally, the amount of the sensitizing element in the non-volatile components can be obtained based on the amount of the sensitizing element in the material used, but in terms of knowing the amount of the sensitizing element contained in the final resin composition for forming an upper layer film itself, the amount of the sensitizing element in the non-volatile components may be obtained by X-ray photoelectron spectroscopy.

Specifically, the amount of the sensitizing element in the non-volatile components can be quantitatively determined by analyzing the energy of photoelectrons generated by irradiating a film, which is formed by applying the resin composition for forming an upper layer film onto the substrate and then volatilizing a volatile component, with an X-ray. In the following examples, the amount of the sensitizing element is obtained in this manner.

### (Preferable Sensitizing Element)

As described above, the sensitizing element may be one or more selected from the group consisting of Ge, Mo, Hf, Zr, Ta, W, Cr, Co, Fe, Pt, Sn, and Sb. Among these, from the viewpoint of the generation efficiency of secondary electrons, ease of incorporation into the composition, compatibility with other components in the composition, and the like, Ge, Mo, and W are preferable, Ge and W are more preferable, and Ge is particularly preferable.

Incidentally, Ge, Mo, and W have an aspect that the elements are easily removed by a fluorine-based etching gas. That is, it is considered that by using Ge, Mo, or W as the sensitizing element, a part of the upper layer film, which is unintentionally left on the substrate in the method for forming a pattern described later, can be removed by the subsequent etching.

### (Aspect In Which Resin Contains Sensitizing Element)

The resin composition for forming a resist upper layer film according to the present embodiment may contain the sensitizing element in any form.

As a preferable aspect, the resin composition for forming a resist upper layer film according to the present embodiment contains a resin containing a sensitizing element. It is considered that since the resin contains the sensitizing element, the sensitizing element is easily and relatively uniformly distributed in the upper layer film. When the sensitizing element is uniformly distributed in the upper layer film, secondary electrons can be generated in an amount corresponding to the irradiation amount of EUV light at any location in the upper layer film, and thus this case is preferable.

The resin containing the sensitizing element preferably has an alkali-soluble group. When the resin has an alkali-soluble group, the upper layer film can be removed with an alkaline developer in the lithography process.

Examples of the alkali-soluble group include a carboxy group, a phenolic hydroxy group, and a hexafluoroisopropanol group (—C(CF₃)₂—OH).

From the ease of synthesis, solvent solubility, ease of use as the resin composition for forming a resist upper layer film, and the like, it is preferable that the resin containing the sensitizing element includes a polysiloxane-based resin containing a sensitizing element. More specifically, the resin containing the sensitizing element preferably includes a polysiloxane-based resin in which a part of Si atoms of polysiloxane is replaced by the sensitizing element.

More preferable is a resin having a constitutional unit represented by General Formula (1) and a constitutional unit represented by General Formula (1-A).

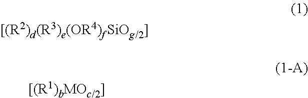

In General Formula (1),

in a case where a plurality of R²'s are present, R²'s are each independently a hydrogen atom, a hydroxy group, a halogen atom, an alkyl group, an alicyclic group, an aryl group, or an alkoxy group,

in a case where a plurality of R³'s are present, R³'s are each independently a hydrogen atom, an alkyl group, an alicyclic group, or an aryl group,

in a case where a plurality of R⁴'s are present, R⁴'s are each independently a hydrogen atom, an alkyl group, an alicyclic group, or an aryl group,

d is a number of 1 or more and 3 or less, e is a number of 0 or more and 2 or less, f is a number of 0 or more and less than 3, g is a number of more than 0 and 3 or less, and d+e+f+g=4.

In General Formula (1-A),

M is one or more elements selected from the group consisting of Ge, Mo, Hf, Zr, Ta, W, Cr, Co, Fe, Pt, Sn, and Sb (that is, at least any one of the above-described sensitizing elements),

in a case where a plurality of R¹'s are present, R¹'s are each independently a hydrogen atom, a hydroxy group, a halogen atom, an alkyl group, an alicyclic group, an alkoxy group, or an aryl group,

b is a number of 0 or more and less than 6, c is a number of more than 0 and 6 or less, and b+c=3 to 6.

Hereinafter, General Formula (1) and General Formula (1-A) will be described in more detail.

### General Formula (1)

In General Formula (1), as theoretical values of d, e, f, and g, d is an integer of 1 to 3, e is an integer of 0 to 2, f is an integer of 0 to 3, and g is an integer of 0 to 3. In addition, d+e+f+g=4 means that the sum of the theoretical values is 4. However, for example, in the value obtained by ²⁹Si NMR measurement, d may be a decimal that would be 1 or more and 3 or less when rounded, e may be a decimal that would be 0 or more and 2 or less when rounded, f may be a decimal that would be 0 or more and 2 or less when rounded (where f<3.0), and g may be a decimal that would be 0 or more and 3 or less when rounded (where g≠0).

In addition, O_{g/2} in General Formula (1) is generally used as a representation of a compound having a siloxane bond. Formula (1-1) represents a case where g is 1, Formula (1-2) represents a case where g is 2, and Formula (1-3) represents a case where g is 3. In the case where g is 1, the constitutional unit is positioned at the end of the siloxane chain in the compound having the siloxane bond.

In General Formulae (1-1) to (1-3), Rx has the same meaning as R² in General Formula (1), and R^{a} and R^{b} each independently have the same meaning as R², R³, and OR⁴ in General Formula (1). The broken lines represent bonds with other Si atoms.

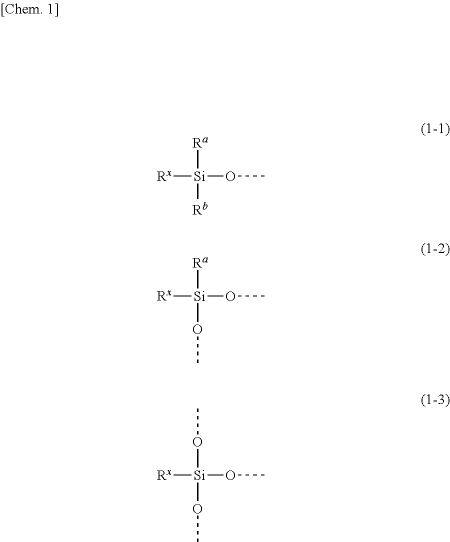

Examples of the alkyl group of R², R³, and R⁴ in General Formula (1) include a methyl group, an ethyl group, an n-propyl group, an isopropyl group, a butyl group, an isobutyl group, a tert-butyl group, an n-pentyl group, an isopentyl group, a neopentyl group, a hexyl group, and an octyl group. Among these, a methyl group and an ethyl group are preferable.

The number of carbon atoms in the alkyl group is, for example, 1 to 12, preferably 1 to 10 and more preferably 1 to 6.

Examples of the alicyclic group of R², R³, and R⁴ in General Formula (1) include a cyclopentyl group, a cyclohexyl group, a cycloheptyl group, a cyclooctyl group, a norbornyl group, and an adamantyl group. The alicyclic group may have a monocyclic structure or a polycyclic structure.

The number of carbon atoms in the alicyclic group is, for example, 5 to 20, preferably 5 to 16, and more preferably 5 to 10.

Examples of the aryl group of R², R³, and R⁴ in General Formula (1) include a phenyl group and a naphthyl group. The number of carbon atoms in the aryl group is, for example, 5 to 20, preferably 5 to 16, and more preferably 5 to 10.

Examples of the alkoxy group of R² in General Formula (1) include an aspect in which in General Formula —O—R²′, R²′ is the above-mentioned alkyl group.

The halogen atom of R² in General Formula (1) is preferably a fluorine atom.

The alkyl group, alkoxy group, alicyclic group, or aryl group of R² may further have a substituent or may not have a substituent. Similarly, the alkyl group, alicyclic group, or aryl group of R³ may further have a substituent or may not have a substituent. Similarly, the alkyl group, alicyclic group, or aryl group of R⁴ may further have a substituent or may not have a substituent.

The substituent is not particularly limited, and examples thereof include an alkyl group, an alicyclic group, an aryl group, and a halogen atom. Of course, substituents other than these may be used. In addition, the substituent may be an alkali-soluble group described below.

A preferable substituent is a halogen atom, and a more preferable substituent is a fluorine atom. For example, the above-described alkyl group may be a fluorinated alkyl group.

In a case where R², R³, and R⁴ in General Formula (1) are carbon-containing groups, the total number of carbon atoms in each atomic group is, for example, 1 to 20, preferably 1 to 16, and more preferably 1 to 12.

As described above, in order to make the upper layer film removable with an alkaline developer in the lithography process, the resin containing the sensitizing element preferably has an alkali-soluble group.

In the resin having the constitutional unit represented by General Formula (1) and the constitutional unit represented by General Formula (1-A), it is preferable that at least any of R¹ to R⁴ includes an alkali-soluble group. In other words, it is preferable that at least any of R¹ to R⁴ is substituted with an alkali-soluble group.

Specifically, it is preferable that at least R² includes an alkali-soluble group.

Examples of the alkali-soluble group include a carboxy group, a phenolic hydroxy group, and a hexafluoroisopropanol group (—C(CF₃)₂—OH).

In particular, it is preferable that R² includes a group represented by General Formula (1a).

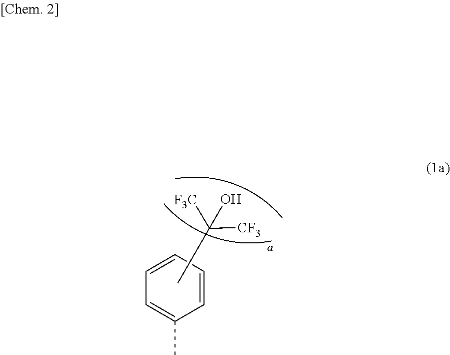

In General Formula (1a),

a is a number of 1 to 5, and

the broken line represents a bond.

In particular, the group represented by General Formula (1a) is preferably any of groups represented by General Formulae (1aa) to (1ad). In General Formulae (1aa) to (1ad), the definitions of X and the broken line are the same as the definitions in General Formula (1a).

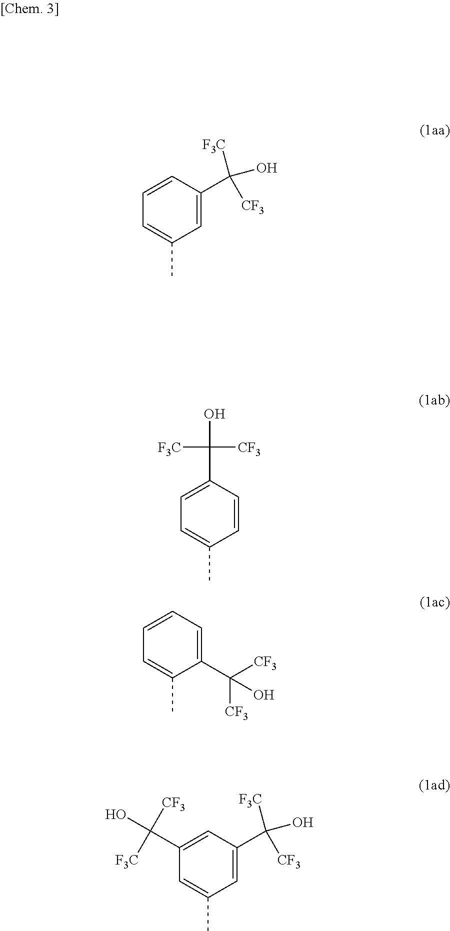

### General Formula (1-A)

In General Formula (1-A), as theoretical values of b and c, b is an integer of 0 to 6 and c is an integer of 0 to 6. In addition, b+c=3 to 6 means that the sum of the theoretical values is 3 to 6. However, for example, in the value obtained by polynuclear NMR measurement, each of b and c is obtained as an average value. Therefore, b as the average value may be a decimal that would be 0 or more and 6 or less when rounded (where b<6.0), and c as the average value may be a decimal that would be 0 or more and 6 or less when rounded (where c≠0). Incidentally, the theoretical value c=0 indicates that the constitutional unit is a monomer, and the average value c≠0 indicates that all of the compounds are not monomers.

Specific examples of the halogen atom, alkyl group, alicyclic group, alkoxy group, and aryl group in General Formula (1-A) include the groups mentioned as the specific examples of R² in General Formula (1).

It is considered that M in General Formula (1-A) is preferably Ge, Sn, or Pb, which is in the same group as Si. Among these, particularly, from the viewpoint of easily removing the sensitizing element unintentionally left on the resist in the subsequent fluorine-based etching step, it is preferable that M includes Ge. In addition, from the same viewpoint, it is particularly preferable that M includes one or more selected from the group consisting of Ge, Mo, and W.

Preferable examples of a monomer (raw material) corresponding to the constitutional unit represented by General Formula (1-A) include germanium tetramethoxide, germanium tetraethoxide, germanium tetrapropoxide, germanium tetrabutoxide, germanium tetraamyloxide, germanium tetrahexyloxide, germanium tetracyclopentoxide, germanium tetracyclohexyloxide, germanium tetraaryloxide, germanium tetraphenoxide, germanium (mono, di, or tri) methoxy (mono, di, or tri) ethoxide, germanium (mono, di, or tri) ethoxy (mono, di, or tri) propoxide, molybdenum tetraethoxide, tungsten tetraethoxide, tungsten tetraphenoxide, germanium tetrachloride, germanium tetrabromide, germanium methyltrichloride, and germanium phenyltrichloride.

### Other Constitutional Units That May Be Included

The resin having the constitutional unit represented by General Formula (1) and the constitutional unit represented by General Formula (1-A) may further include another constitutional unit.

A preferable example of “another constitutional unit” includes a constitutional unit represented by General Formula (2).

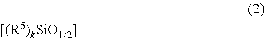

In General Formula (2),
in a case where a plurality of R⁵'s are present, R⁵'s are each independently a halogen atom, an alkoxy group, or a hydroxy group,
k is a number of 0 or more and less than 4, 1 is a number of more than 0 and 4 or less, and k+1=4.
k is preferably a number of 0 or more and 3 or less. 1 is preferably a number of 1 or more and 4 or less.

As the halogen atom of R⁵, a fluorine atom is preferable.

Examples of the alkoxy group of R⁵ include an aspect in which, in General Formula —O—R⁵′, R⁵′ is an alkyl group such as a methyl group, an ethyl group, an n-propyl group, an isopropyl group, an n-butyl group, an isobutyl group, a tert-butyl group, an n-pentyl group, an isopentyl group, a neopentyl group, a hexyl group, or an octyl group. The number of carbon atoms in the alkoxy group is, for example, 1 to 12, preferably 1 to 10, and more preferably 1 to 6.

In the third constitutional unit represented by General Formula (2), as theoretical values of k and 1, k is an integer of 0 to 4, and 1 is an integer of 0 to 4. In addition, k+0.1=4 means that the sum of the theoretical values is 4. However, for example, in the value obtained by ²⁹Si NMR measurement, each of k and 1 is obtained as an average value. Therefore, k as the average value may be a decimal that would be 0 or more and 4 or less when rounded (where k<4.0), and 1 may be a decimal that would be 0 or more and 4 or less when rounded (where 1≠0).

For O_{1/2} in General Formula (2), O_{1/2} in a case where 1=4 represents General Formula (2-1). In General Formula (2-1), the broken lines represent bonds with other Si atoms.

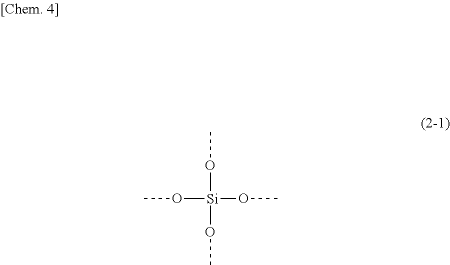

O_{4/2} in General Formula (2) is generally called a Q4 unit, and shows a structure in which all four bonds of a Si atom form siloxane bonds. Although Q4 has been described above, General Formula (2) may contain a hydrolyzable and condensable group in the bond as in Q0, Q1, Q2, and Q3 units shown below. In addition, General Formula (2) may have at least one selected from a group consisting of Q1 to Q4 units.

Q0 unit: a structure in which all four bonds of a Si atom are hydrolyzable and polycondensable groups (such as a halogen group, alkoxy group, or hydroxy group that can form siloxane bonds).

Q1 unit: a structure in which one of the four bonds of a Si atom forms a siloxane bond and the other three are all hydrolyzable and polycondensable groups.

Q2 unit: a structure in which two of the four bonds of a Si atom form a siloxane bond and the other two are all hydrolyzable and polycondensable groups.

Q3 unit: a structure in which three of the four bonds of a Si atom form a siloxane bond and the other one is the hydrolyzable and polycondensable group.

Preferable examples of a monomer (raw material) corresponding to the constitutional unit represented by General Formula (2) include tetraalkoxysilane, tetrahalosilane (for example, tetrachlorosilane, tetramethoxysilane, tetraethoxysilane, tetra-n-propoxysilane, tetraisopropoxysilane, or the like), and an oligomer of these compounds.

In the resin containing the sensitizing element, the content ratio (copolymerization ratio) of the constitutional unit represented by General Formula (1) is preferably 10 to 60 mol %, and more preferably 20 to 50 mol %.

From the viewpoint of further improving the sensitivity by allowing a larger amount of the sensitizing element to be present in the resist upper layer film, the content ratio (copolymerization ratio) of the constitutional unit represented by General Formula (1-A) in the resin containing the sensitizing element is preferably 10 to 60 mol %, and more preferably 20 to 50 mol %.

In a case where the resin containing the sensitizing element has the constitutional unit represented by General Formula (2), the content ratio (copolymerization ratio) thereof is preferably 10 to 60 mol %, and more preferably 20 to 50 mol %. From the viewpoint of solubility in an alkaline developer and solubility/dispersibility in a solvent in the resin composition for forming a resist upper layer film, the content ratio (copolymerization ratio) of the constitutional unit having an alkali-soluble group in the resin containing the sensitizing element is 10 to 60 mol %, and more preferably 20 to 50 mol %.

The weight average molecular weight of the resin containing the sensitizing element is not particularly limited, and is, for example, 500 to 50,000, preferably 800 to 40,000, and more preferably 1,000 to 30,000.

The resin containing the sensitizing element can be synthesized, for example, by hydrolysis and polycondensation of (i) at least one selected from the group consisting of halosilanes and alkoxysilanes, and (ii) at least one selected from the group consisting of alkoxides and halides of one or more elements selected from the group consisting of Ge, Mo, Hf, Zr, Ta, W, Cr, Co, Fe, Pt, Sn, and Sb and a halide of the element, which correspond to each constitutional unit described above.

Incidentally, these (i) and (ii) may be referred to as “raw material compounds corresponding to each constitutional unit” in the following description.

As a specific procedure for the synthesis, first, the raw material compounds corresponding to each constitutional unit are collected in a reaction vessel at room temperature (in particular, an ambient temperature not heated or cooled, and usually about 15° C. to 30° C.; the same shall apply hereinafter). Thereafter, water for hydrolyzing the raw material compounds corresponding to each constitutional unit, a catalyst for causing the polycondensation reaction to proceed, and, if desired, a reaction solvent are added to the reaction vessel to form a reaction solution. The addition order at this time is not particularly limited thereto.

Next, the reaction solution is stirred, and the hydrolysis and condensation reaction are allowed to proceed at a predetermined temperature for a predetermined period of time. In this manner, a resin can be obtained. The time required for the reaction depends on the type of the catalyst, and is usually 3 to 24 hours, and the reaction temperature is room temperature (for example, 25° C.) or higher and 200° C. or lower.

In a case where heating is performed, in order to prevent the unreacted raw material, water, the reaction solvent, and/or the catalyst in the reaction system from being distilled off to the outside of the reaction system, it is preferable that the reaction vessel is a closed system or a reflux device is attached to reflux the reaction system. After the reaction, from the viewpoint of handling of the resin composition, it is preferable to reduce water remaining in the reaction system, the alcohol to be formed, and the catalyst. Examples of the specific method include (i) an extraction operation and (ii) a method in which a solvent, such as toluene, which does not adversely affect the reaction, is added to the reaction system and azeotropically removed in a Dean-Stark tube.

The amount of water used in the hydrolysis and condensation reactions is not particularly limited. From the viewpoint of reaction efficiency, the amount is preferably 0.01 to 15 times with respect to the total number of moles of the hydrolyzable groups (an alkoxy group or a halogen atom group, and in a case of including both, an alkoxy group and a halogen atom group) contained in the raw material compounds corresponding to each constitutional unit.

The catalyst for causing the polycondensation reaction to proceed is not particularly limited, and an acid catalyst or a base catalyst is preferably used.

Specific examples of the acid catalyst include hydrochloric acid, nitric acid, sulfuric acid, hydrofluoric acid, phosphoric acid, acetic acid, oxalic acid, trifluoroacetic acid, methanesulfonic acid, trifluoromethanesulfonic acid, camphorsulfonic acid, benzenesulfonic acid, tosylic acid, a polyvalent carboxylic acid such as formic acid, maleic acid, malonic acid, or succinic acid, or anhydrides thereof.

Specific examples of the base catalyst include triethylamine, tripropylamine, tributylamine, tripentylamine, trihexylamine, triheptylamine, trioctylamine, diethylamine, triethanolamine, diethanolamine, sodium hydroxide, potassium hydroxide, sodium carbonate, and tetramethylammonium hydroxide. The amount of the catalyst used is preferably 0.001 to 0.5 times with respect to the total number of moles of the hydrolyzable groups (an alkoxy group or a halogen atom group, and in a case of including both, an alkoxy group and a halogen atom group) included in the raw material compounds corresponding to each constitutional unit.

In the hydrolysis and condensation reaction, the reaction solvent is not necessarily used, and the raw material compound, water, and the catalyst can be mixed and hydrolyzed and condensed. On the other hand, in a case where a reaction solvent is used, the type thereof is not particularly limited. Among these, from the viewpoint of solubility of the raw material compound, water, and the catalyst, a polar solvent is preferable, and an alcohol-based solvent is more preferable. Specifically, one or two or more of methanol, ethanol, 1-propanol, 2-propanol, 1-butanol, 2-butanol, diacetone alcohol, and propylene glycol monomethyl ether may be used. As the amount to be used in a case where the reaction solvent is used, any amount necessary for the hydrolysis condensation reaction to proceed in a homogeneous system can be used.

It is preferable to reduce unreacted monomers and impurities in the synthesized resin by a method commonly known in the field of polymer chemistry, such as dilution, concentration, extraction, washing with water, ion exchange resin purification, filtration with a solvent, or the like.

### (Aspect in Which Component Containing Sensitizing Element is Added Separately From Resin)

Regarding a form in which the resin composition for forming a resist upper layer film of the present embodiment contains the sensitizing element, as another preferable aspect, a resin composition for forming a resist upper layer film that contains a resin and an additive component containing a sensitizing element as a component separate from the resin can be used. In this case, the resin may contain the sensitizing element as described above or may not contain the sensitizing element.

In a case where the resin contains the sensitizing element, the specific aspects of the resin are as described above.

As the specific aspect of the resin in a case where the resin does not contain the sensitizing element, for example, the same resin as the above-described polysiloxane-based resin, except that the resin does not have the constitutional unit having the sensitizing element (that is, a resin that does not have the sensitizing element-containing constitutional unit as represented by General Formula (1-A), but has the constitutional unit represented by General Formula (1), and may have the constitutional unit represented by General Formula (2) or the like) can be used. From the viewpoint of solvent solubility, uniform applicability, and other various performance, a polysiloxane-based resin is preferable. In addition, as the resin not containing the sensitizing element, a (meth) acrylic resin may also be preferable. The (meth) acrylic resin is also used in resin compositions for forming a resist upper layer film in the related art, and is preferable from the viewpoint of solvent solubility, uniform applicability, and other various performance.

From the viewpoint of making the upper layer film removable with an alkaline developer, it is preferable that the (meth) acrylic resin also has an alkali-soluble group. Examples of the alkali-soluble group include a carboxy group, a phenolic hydroxy group, and a hexafluoroisopropanol group (—C(CF₃)₂—OH).

Examples of a suitable (meth) acrylic resin include a (meth) acrylic resin having a constitutional unit represented by General Formula (X).

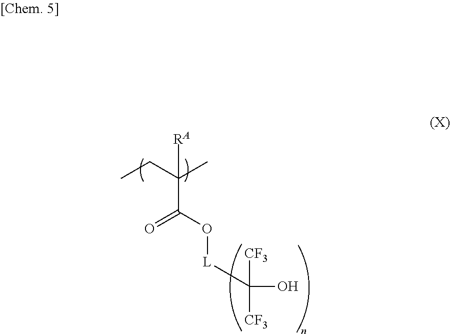

In General Formula (X),
R^{A} is a hydrogen atom or a methyl group,
L is an (n +1)-valent atomic group, and
n is an integer of 1 or more.

L is preferably an (n+1)-valent organic group. L is more preferably a group obtained by removing n hydrogen atoms from an alkyl group, a monovalent alicyclic group, or an aryl group. Specific examples of the alkyl group, the monovalent alicyclic group, and the aryl group herein include the groups each mentioned as the examples of R² in General Formula (1). The number of carbon atoms in L is, for example, 1 to 12, and specifically 1 to 10.

n is preferably 1 to 3 and more preferably 1 or 2.

The (meth) acrylic resin may have a constitutional unit other than those described above.

The weight average molecular weight of the resin not containing the sensitizing element is not particularly limited, and is, for example, 500 to 50,000, preferably 800 to 40,000, and more preferably 1,000 to 30,000.

In the aspect in which the component containing the sensitizing element is added separately from the resin, the resin preferably has an alkali-soluble group (for example, the above-described hexafluoroisopropanol group (—C(CF₃)₂—OH) or the like). When the resin has an alkali-soluble group, the upper layer film can be removed with an alkaline developer in the lithography process.

The additive component is not limited as long as it contains one or more sensitizing elements selected from the group consisting of Ge, Mo, Hf, Zr, Ta, W, Cr, Co, Fe, Pt, Sn, and Sb. The additive component can be an organic compound containing a sensitizing element, an inorganic compound containing a sensitizing element, or the like. The additive component may be appropriately selected from the viewpoint of improving sensitivity, and also from the viewpoint of solvent solubility, compatibility with the resin, and the like. The organic compound containing the sensitizing element is preferable in that the compound is easily satisfactorily dissolved or dispersed in an organic solvent, and as a result, the sensitizing element is easily uniformly distributed in the upper layer film.

Among these, from the viewpoint of availability, compatibility with the resin, further improvement in sensitivity, and the like, an organic germanium compound, an organic molybdenum compound, an organic tungsten compound, an inorganic germanium compound, an inorganic molybdenum compound, an inorganic tungsten compound, and the like are preferable. Among these, an organic germanium compound and an inorganic tungsten compound are preferable.

In particular, from the viewpoint of availability, the additive component preferably includes one or more selected from the group consisting of tetraethoxygermanium, silicotungstic acid, and bis [2-carboxyethylgermanium (IV)] sesquioxide.

Incidentally, the additive component may be an oxide of the above-described sensitizing element (metal oxide or the like). However, the metal oxide is usually insoluble in an organic solvent, and in order to uniformly disperse the metal oxide, it is necessary to use a dispersant, apply ultrasonic waves, or the like. Thus, the metal oxide is not preferable.

### (Solvent)

The resin composition for forming a resist upper layer film according to the present embodiment usually contains a solvent. In other words, the resin composition for forming a resist upper layer film according to the present embodiment is usually a composition obtained by dissolving or dispersing the above-described resin containing the sensitizing element, the resin not containing the sensitizing element, the additive component containing the sensitizing element, and the like in a solvent.

The solvent is typically an organic solvent. As the solvent, a solvent which can dissolve or disperse the above-described resin containing the sensitizing element, the resin not containing the sensitizing element, the additive component containing the sensitizing element, and the like and which does not substantially dissolve the photoresist film is preferably used. In consideration of the process of forming a film by volatilizing the solvent, the boiling point of the solvent is preferably 100° C. to 200° C.

Suitable examples of the solvent include alcohol-based solvents, that is, compounds having an alcohol-based hydroxy group in the molecule. Specific examples of the alcohol-based solvents include n-amyl alcohol, isoamyl alcohol, 1-butanol, 1-octanol, 2-octanol, 4-methyl-2-pentanol, 1-hexanol, 3-heptanol, i-butyl alcohol, 2-ethyl-1-butanol, 2-ethyl-1-hexanol, 1-nonanol, neopentyl alcohol, cyclohexanol, tetrahydrofurfuryl alcohol, and structural isomers thereof.

In addition, examples of the solvent also include (i) non-polar solvents such as hydrocarbon-based solvents, halogenated hydrocarbon solvents, and fluorine-containing non-polar solvents, and (ii) polar solvents such as ether-based solvents, nitrogen-containing solvents, carboxylic acid-based solvents, acid anhydride-based solvents, ester-based solvents, and ketone-based solvents.

The resin composition for forming a resist upper layer film according to the present embodiment may contain only one solvent, or may contain two or more solvents. As long as the contained components are appropriately dissolved or dispersed and the upper layer film can be formed without substantially invading the photoresist film, the type and mixing ratio of the solvent are not particularly limited.

The non-volatile component concentration of the resin composition for forming a resist upper layer film according to the present embodiment is, for example, 0.001% to 10% by mass, preferably 0.01% to 7% by mass, and more preferably 0.1% to 5% by mass. It is preferable that the amount of the solvent used is adjusted such that the non-volatile component concentration of the resin composition for forming a resist upper layer film is within the above range.

The non-volatile component concentration may be appropriately adjusted in consideration of the thickness of the upper layer film to be formed and the conditions of film formation (such as a rotation speed in a case of spin coating).

### (Others)

The resin composition for forming a resist upper layer film according to the present embodiment may contain one or two or more optional components for adjusting performance, in addition to the above-described components, or may not contain the optional component.

Examples of the optional component include a surfactant, an antioxidant, and an antifoaming agent.

The resin composition for forming a resist upper layer film according to the present embodiment is usually non-photosensitive. In other words, the resin composition for forming a resist upper layer film according to the present embodiment usually does not substantially contain a photoacid generator, and a fine pattern cannot be formed by exposure using only the resin composition for forming a resist upper layer film.

The resin composition for forming a resist upper layer film according to the present embodiment is usually used in an EUV lithography process. The specific aspect of the EUV lithography process will be specifically described in the section of “Method for Forming Pattern and Method for Producing Electronic Device” below.

### Method for Forming Pattern and Method for Producing Electronic Device

A method for forming a pattern using the above-described resin composition for forming a resist upper layer film and a method for producing an electronic device will be described with reference to the accompanying drawings.

The method for forming a pattern may include
a photoresist film forming step of forming a photoresist film over a substrate,
a resist upper layer film forming step of forming a resist upper layer film over the photoresist film using the above-described resin composition for forming a resist upper layer film,
an exposing step of exposing the photoresist film and the resist upper layer film, and
a developing step of removing at least a part of the photoresist film using a developer.

Hereinafter, each step will be described with reference to the accompanying drawings.

### (Photoresist Film Forming Step: FIG. 1)

In the photoresist film forming step, a photoresist film 20 is formed on at least one surface of a substrate 10.

The photoresist for forming the photoresist film 20 is not particularly limited. The photoresist may be a positive photoresist in which solubility in a developer is increased by irradiation with EUV light, or may be a negative photoresist in which solubility in a developer is decreased by irradiation with EUV light. From the viewpoint of good sensitivity, a chemically amplified type photoresist is usually used as the photoresist.

The positive photoresist is usually a composition obtained by dissolving or dispersing at least an acid-decomposable resin and an acid generator in a solvent. In the EUV lithography, secondary electrons generated by irradiation with EUV light decompose the acid generator to generate an acid. This acid eliminates the protective group in the acid-decomposable resin, and thus the solubility in an alkaline developer is increased.

The negative photoresist is usually a composition obtained by dissolving or dispersing at least a resin, a crosslinking agent, and a compound which generates an active chemical species in response to an external stimulus (an acid generator, a radical generator, or the like) in a solvent. In the EUV lithography, the secondary electrons generated by the irradiation with EUV light act on the compound, which generates an active chemical species in response to an external stimulus, to generate the active chemical species. By the action of the active chemical species, a covalent bond is formed between the resin and the crosslinking agent or between the crosslinking agent and the crosslinking agent. As a result, the composition is insoluble or difficult to dissolve in a developer (that is, turned to be negative).

It should be noted that, as long as the solubility in a developer is changed by the irradiation with EUV light, any photoresist can be used. For example, a non-chemically amplified resist can also be used in addition to the chemically amplified type resist.

The photoresist film 20 is usually formed by applying a photoresist onto the substrate by a spin coating method. That is, first, an appropriate amount of a photoresist (containing a solvent) is provided on the substrate 10, and then the substrate 10 is rotated to spread the photoresist thinly over the substrate 10. Thereafter, heating (baking) for drying the remaining solvent may be performed as necessary.

The thickness of the photoresist film 20 is preferably 30 nm or less, more preferably 1 to 30 nm, still more preferably 10 to 30 nm, and particularly preferably 15 to 30 nm. It is considered that, when the photoresist film 20 is not too thick, the secondary electrons generated in a resist upper layer film 30 (refer to FIG. 2) sufficiently move not only to the upper part of the photoresist film 20 but also to the lower part. As a result, it is considered that the sensitivity improving effect can be reliably obtained, and the shape of the final resist pattern can be appropriately adjusted.

As the substrate 10, a silicon substrate is often used, but the substrate can be any substrate.

Incidentally, any underlayer film may be provided on an upper surface (a surface on a side where the photoresist film 20 is formed) of the substrate 10 (not shown in FIG. 1). Of course, the substrate may be a substrate on which a film is not provided (for example, a bare silicon substrate).

### (Resist Upper Layer Film Forming Step: FIG. 2)

In the resist upper layer film forming step, the resist upper layer film 30 is provided on an upper surface (a surface on the side opposite to the substrate 10) of the photoresist film 20. The resist upper layer film 30 is usually provided by a spin coating method in the same manner as in the formation of the photoresist film 20. Of course, methods other than the spin coating method can also be applied.

The thickness of the resist upper layer film 30 is usually 0.1 to 30 nm, preferably 0.5 to 20 nm and more preferably 1 to 10 nm. It is considered that, in a case where the resist upper layer film 30 has a relatively large thickness, the amount of the sensitizing element contained in the resist upper layer film 30 is sufficiently large. In addition, it is considered that, when the thickness of the resist upper layer film 30 is not too thick, the secondary electrons generated in the resist upper layer film 30 easily reach the photoresist film 20. That is, it is preferable that the resist upper layer film 30 is not too thick or not too thin.

For reference, in the present specification, one in which the photoresist film 20 and the resist upper layer film 30 are laminated on the substrate in this order is referred to as a “laminate”. In addition, the photoresist film 20 and the resist upper layer film 30 laminated on the above-described substrate may be collectively referred to as a “laminated film”.

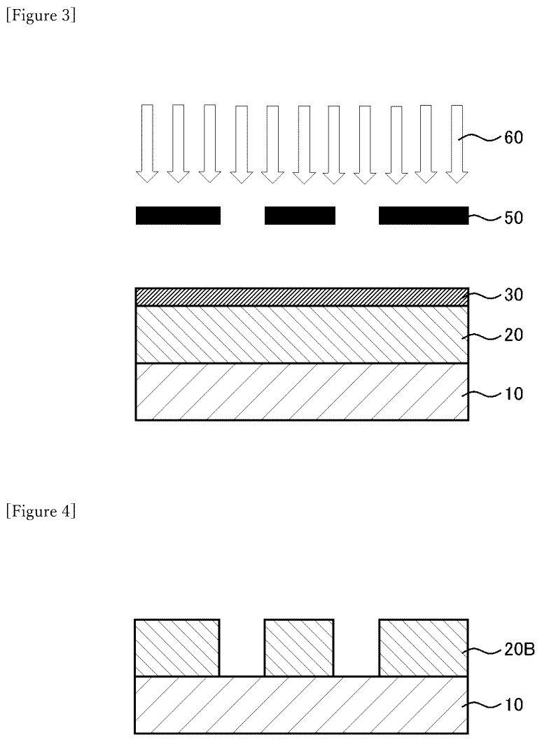

### (Exposing Step: FIG. 3)

In the exposing step, the photoresist film 20 and the resist upper layer film 30 are irradiated with an actinic ray. The exposing step is usually performed by emitting an actinic ray 60 through a photo mask 50 as shown in FIG. 3.

The wavelength of the actinic ray is, for example, 1 to 600 nm, and preferably 6 to 27 nm. In the present embodiment, the actinic ray is preferably EUV light. That is, the exposing step is preferably performed using EUV light. The wavelength of EUV generally used is 13.5 nm. In addition, the pulse width of the EUV light is usually 0.1 to 40 nm, and the intensity of the EUV light is usually 100 to 1,000 kW.

In the exposing step, the mass productivity is deteriorated, but an electron beam can also be used.

The exposure amount may be appropriately set according to the sensitivity of the photoresist film 20.

### (Developing Step: FIG. 4)

In the developing step, at least a part of the photoresist film 20 is removed using a developer. In this manner, a pattern 20B is formed. In a case where a positive photoresist is used as the photoresist and an alkaline developer is used as the developer, a portion exposed in the exposing step is usually removed by the developer. On the other hand, in a case where a negative photoresist is used as the photoresist, a portion which is not exposed in the exposing step is usually removed by the developer.

As the alkaline developer, alkaline aqueous solutions of inorganic alkalis such as sodium hydroxide, potassium hydroxide, sodium carbonate, sodium silicate, sodium metasilicate, and ammonium water, primary amines such as ethylamine and n-propylamine, secondary amines such as diethylamine and di-n-butylamine, tertiary amines such as triethylamine and methyldiethyl amine, alcohol amines such as dimethylethanolamine and triethanolamine, quaternary ammonium salts such as tetramethylammonium hydroxide and tetraethylammonium hydroxide, cyclic amines such as pyrrole and piperidine, and the like can be used. To the alkaline aqueous solution, alcohol and a surfactant may further be added in appropriate amounts.

As the alkaline developer, an aqueous solution of tetramethylammonium hydroxide is preferable.

As the developer, in addition to the alkaline developer, an organic solvent-based developer, that is, a developer containing an organic solvent as a main component (for example, a developer containing 90% by mass or more of an organic solvent) can also be used. For development with an organic solvent, reference can be made to the description in, for example, Japanese Unexamined Patent Publication No. 2008-292975. Incidentally, in a case where a photoresist in which an acid-decomposable resin and an acid generator are dissolved or dispersed in a solvent (a positive pattern is formed when performing development with an alkaline developer) is used as the photoresist and development is performed with an organic solvent, a negative pattern is usually formed.

Examples of the organic solvent-based developer include developers containing a ketone-based solvent, an ester-based solvent, an alcohol-based solvent, or the like as a main component.

Specific examples include developers containing, as a main component, acetophenone, methyl acetophenone, diisobutyl ketone, 2-hexanone, 3-hexanone, 2-heptanone, 3-heptanone, 4-heptanone, 2-octanone, 2-nonanone, methylcyclohexanone, propyl formate, butyl formate, isobutyl formate, pentyl formate, isopentyl formate, propyl acetate, butyl acetate, isobutyl acetate, pentyl acetate, isopentyl acetate, 2-methylbutyl acetate, hexyl acetate, butenyl acetate, methyl propionate, ethyl propionate, methyl lactate, ethyl lactate, propyl lactate, butyl lactate, isobutyl lactate, pentyl lactate, isopentyl lactate, ethyl 3-ethoxypropionate, methyl 2-hydroxyisobutyrate, ethyl 2-hydroxyisobutyrate, methyl crotonate, ethyl crotonate, methyl valerate, methyl pentenoate, methyl benzoate, benzyl formate, phenyl acetate, ethyl benzoate, phenylethyl formate, benzyl acetate, methyl phenylacetate, ethyl phenylacetate, 2-phenylethyl acetate, methyl 3-phenylpropionate, benzyl propionate, ethanol, 1-propanol, 2-propanol, and the like. Among these, from the viewpoint of availability and workability, butyl acetate is preferable.

These organic solvents may be used alone or as a mixture of two or more thereof. The organic solvent-based developer may contain only these organic solvents, and may contain other components in addition to the organic solvents as long as the performance as a developer is not impaired. Examples of the other components include a surfactant and the like. Examples of the surfactant include fluorine-based surfactants and silicone-based surfactants.

### (Removal of Upper Layer Film 30)

The upper layer film 30 may be removed together with a part of the photoresist film 20 in the developing step, or may be removed by performing an additional step of removing the upper layer film 30 between the exposing step and the developing step.

As described above, since the resin contained in the upper layer film 30 has an alkali-soluble group, the upper layer film 30 can be removed together with a part of the photoresist film 20 in the developing step.

In a case where the upper layer film 30 is removed between the exposing step and the developing step, as a specific method thereof, a method of dissolving and removing the upper layer film 30 using a solvent which dissolves the upper layer film 30 but does not substantially dissolve the photoresist film 20 may be used. Examples of the solvent used in such a method include the above-described solvents which can be contained in the resin composition for forming a resist upper layer film according to the present embodiment (preferably, alcohol-based solvents and the like).

### (Producing of Electronic Device)

The pattern 20B obtained as shown in FIG. 4 can be used as a mask in dry etching to selectively process the substrate 10. In addition, an electronic device can be produced by applying various known processes in the producing of the electronic device to the substrate processed in this manner.

Although the embodiments of the present invention have been described above, these are examples of the present invention, and various configurations other than the above can be adopted. Further, the present invention is not limited to the above-described embodiments, and modifications, improvements, and the like within a range in which the object of the present invention can be achieved are included in the present invention.

### EXAMPLES

A detailed description will be given of embodiments of the present invention based on Examples and Comparative Examples. It should be noted that the present invention is not limited to Examples only.

### Synthesis of Resin Containing Sensitizing Element and Preparation of Resin Composition for Forming Resist Upper Layer Film

### (Synthesis of Resin Solution 1 Containing Sensitizing Element)

1.92 g (4.7 mmol) of HFA-Si (for the structure, refer to the chemical formula shown below), 2.39 g (9.45 mmol) of germanium tetraethoxide, 1.97 g (9.45 mmol) of tetraethoxysilane, and 6.0 g of ethanol were added to a reaction vessel, and the mixture was stirred at 70° C.

Then, a mixed solution of 18 g of ethanol, 0.48 g of pure water, and 0.14 g of maleic acid (1.2 mmol, a catalyst for causing a polycondensation reaction to proceed) was added dropwise to the reaction vessel, and the mixture was further stirred for 3 hours. The reaction solution finally obtained was a homogeneous solution.

After the stirring was completed, 20 g of 4-methyl-2-pentanol (MIBC) was added to the reaction vessel, and the mixture was treated with an evaporator at 50° C. In this manner, 20 g of a resin solution 1 was obtained. The weight average molecular weight Mw of the resin obtained by the GPC measurement was 6, 500. In addition, the solid content concentration of the resin solution was 22% by mass.

In the resin containing the sensitizing element, the content ratio (copolymerization ratio) of the constitutional unit corresponding to General Formula (1) was 20 mol %, the content ratio (copolymerization ratio) of the constitutional unit corresponding to General Formula (1-A) was 40 mol %, and the content ratio (copolymerization ratio) of the constitutional unit corresponding to General Formula (2) was 40 mol %.

### (Synthesis of Resin Solution 2 Containing Sensitizing Element)

9.55 g (23.5 mmol) of HFA-Si, 5.94 g (23.5 mmol) of germanium tetraethoxide, and 12.0 g of ethanol were added to a reaction vessel, and the mixture was stirred at 70° C. Then, a mixed solution of 36 g of ethanol, 0.96 g of pure water, and 0.28 g of maleic acid (2.4 mmol, a catalyst for causing a polycondensation reaction to proceed) was added dropwise to the reaction vessel, and the mixture was further stirred for 3 hours. The reaction solution finally obtained was a homogeneous solution.

After the stirring was completed, 40 g of MIBC was added to the reaction vessel, and the mixture was treated with an evaporator at 50° C. In this manner, 40 g of a resin solution 2 was obtained. The weight average molecular weight Mw of the resin obtained by GPC measurement was 1,550. In addition, the solid content concentration of the resin solution was 22% by mass.

In the resin containing the sensitizing element, the content ratio (copolymerization ratio) of the constitutional unit corresponding to General Formula (1) was 50 mol %, the content ratio (copolymerization ratio) of the constitutional unit corresponding to General Formula (1-A) was 50 mol %, and the content ratio (copolymerization ratio) of the constitutional unit corresponding to General Formula (2) was 0 mol %.

Incidentally, HFA-Si is a compound represented by the following chemical formula. This compound itself is known. In this case, HFA-Si was prepared with reference to the description in Pamphlet of International Publication No. WO2019/167770.

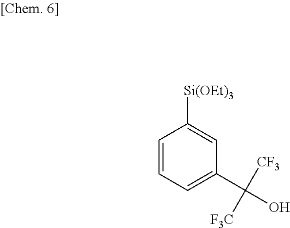

### (Comparative Example 1, Synthesis of Resin Solution 3 Not Containing Sensitizing Element)

3.82 g (9.4 mmol) of HFA-Si, 7.83 g (37.6 mmol) of tetraethoxysilane, and 12.0 g of ethanol were added to a reaction vessel, and the mixture was stirred at 70° C.

Then, a mixed solution of 36 g of ethanol, 0.96 g of pure water, and 0.28 g of maleic acid (2.4 mmol, a catalyst for causing a polycondensation reaction to proceed) was added dropwise to the reaction vessel, and the mixture was further stirred for 3 hours. The reaction solution finally obtained was a homogeneous solution.

After the stirring was completed, 40 g of MIBC was added to the reaction vessel, and the mixture was treated with an evaporator at 50° C. In this manner, 40 g of a resin solution 3 was obtained. The weight average molecular weight Mw of the resin obtained by GPC measurement was 4, 300. In addition, the solid content concentration of the resin solution was 22% by mass.

In the resin, the content ratio (copolymerization ratio) of the constitutional unit corresponding to General Formula (1) was 20 mol %, the content ratio (copolymerization ratio) of the constitutional unit corresponding to General Formula (1-A) was 0 mol %, and the content ratio (copolymerization ratio) of the constitutional unit represented by General Formula (2) was 80 mol %.

### (Preparation of Resin Composition for Forming Resist Upper Layer Film)

MIBC was added to each of the above-described resin solutions 1, 2, and 3, and the solid content concentration was adjusted to 2% by mass. The obtained resin solutions were used as resin compositions 1 to 3 for forming a resist upper layer film, respectively (compositions 1 and 2 for Examples, and composition 3 for Comparative Example).

### Preparation of Resin Composition for Forming Resist Upper Layer Film in Which Component Containing Sensitizing Element Was Added Separately From Resin

0.15 g of homopolymer A (R=Me, Mw=15,000) having the following structure, 9.8 g of MIBC, and 0.05 g of a compound containing a sensitizing element were stirred to prepare resin compositions 4 to 6 (Examples) for forming a resist upper layer film, in which the component containing the sensitizing element was added separately from the resin. In addition, a resin composition 7 (Comparative Example) for forming a resist upper layer film, which did not contain the sensitizing element, was also prepared. Details of each composition are shown in the following table.

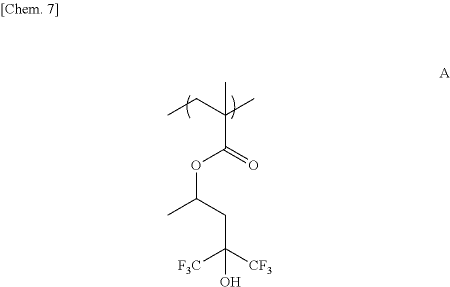

TABLE 1

| Resin | | | |
|---|---|---|---|
| composition for | Homopolymer | Compound containing | Solvent |
| forming upper | (Addition | sensitizing element | (Addition |
| layer film | amount) | (Addition amount) | amount) |
| 4 | A | Tetraethoxygermanium | MIBC |
| | (0.15 g) | (0.05 g) | (9.8 g) |
| 5 | A | Silicotungstic acid | MIBC |
| | (0.15 g) | (0.05 g) | (9.8 g) |
| 6 | A | Bis[2- | MIBC |
| | (0.15 g) | carboxyethylger- | (9.8 g) |
| | | manium(IV)]sesquioxide | |
| | | (0.05 g) | |
| 7 (Comparative | A | — | MIBC |
| Example) | (0.20 g) | | (9.8 g) |

### Formation of Upper Layer Film (Simulation Test)

The resin compositions 1 to 7 for forming an upper layer film described above were filtered through a filter having a pore size of 0.22 μm, each of the filtered resin compositions was applied to a silicon wafer having a diameter of 4 inches and a thickness of 525 μm, produced by SUMCO CORPORATION, by spin coating at a rotation speed of 500 rpm, and then the silicon wafer was baked on a hot plate at 100° C. for 3 minutes. In this manner, upper layer films (simulation films) having a film thickness of 40 to 60 nm were formed on the silicon wafer.

The upper layer film (simulation film) was regarded as an upper layer film formed on the resist film, and various evaluations were performed.

### Evaluation

### (Measurement of Amount of Sensitizing Element in Upper Layer Film (Simulation Film))

The content of each element in the upper layer film (simulation film) obtained as described above was measured by X-ray photoelectron spectroscopy (XPS) as the abundance ratio of the detected element excluding the hydrogen atom. The abundance ratio of the element was calculated from the peak surface area ratio of each detected element. The details of the measurement were as follows.
Device: photoelectron spectrometer produced by JEOL Ltd., equipment name “JPS-9000MC”
X-ray source: MgKx (1253.6 eV)
Measurement range: diameter of 6 mm

### (Measurement of Density of Upper Layer Film)

The thin film density of the upper layer films (simulation films) obtained in Examples 1 to 7 and Comparative Examples 1 and 2 above was measured by an X-ray reflectivity measuring method (XRR). The details of the measurement were as follows.
Device: “smartlab” produced by Rigaku Corporation
Incidence X-ray wavelength: 0.15406 nm (CuKx ray)
Output: 45 kV, 200 mA
Measurement range: 0.0° to 2.0°,
Measurement step: 0.002°

### (Evaluation of Degree of Improvement in Sensitivity: Calculation of EUV Radiation Absorption Amount)

In this case, the amount of secondary electrons generated when the upper layer film (simulation film) of each of Examples and Comparative Examples was irradiated with EUV light (that is, the degree of improvement in sensitivity expected in EUV lithography) was evaluated by calculating the EUV radiation absorption amount.

Incidentally, it is known that the EUV radiation absorption amount is correlated with the amount of secondary electrons generated when the upper layer film is irradiated with EUV light. Since it may be difficult to quantitatively determine the amount of secondary electrons generated by the irradiation with EUV light, the EUV radiation absorption amount is often evaluated instead (for example, paragraph 0113 of Japanese Unexamined Patent Publication No. 2019-094323).

As the value of the EUV radiation absorption amount increases, the amount of secondary electrons generated when the upper layer film is irradiated with EUV light increases, and the degree of improvement in sensitivity tends to be greater.

The radiation absorption amount in the EUV radiation (13.5 nm) was calculated by inputting various information to Center for X-Ray Optics on the website of Lawrence Berkeley National Laboratory. Specifically, the film element composition molecular formula obtained by the XPS and the film density obtained by the XRR were input, and calculation was performed from the above website assuming that the film thickness was 20 nm.

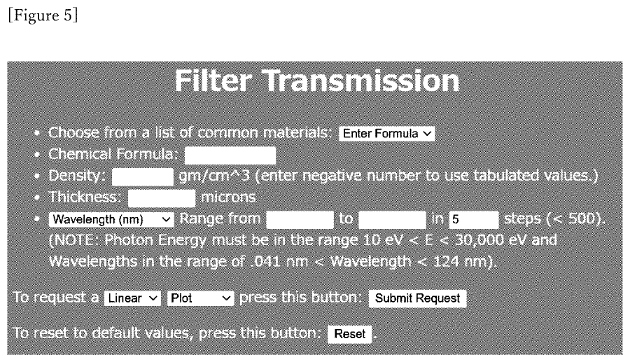

For the sake of clarity, a more specific procedure will be described below.
(1) Access was made to https://henke.lbl.gov/optical_constants/filter2.html. For reference, a screenshot of this website is shown in FIG. 5.
(2) In the column of “Chemical Formula”, the element composition obtained by (Measurement of Amount of Sensitizing Element in Upper Layer Film (Simulation Film)) described above was input in the form of the chemical formula. For example, in a case of the resin composition 1 for forming an upper layer film (C:22 at %, O:35 at %, F:24 at %, Si:10 at %, Ge:9 at %), C22035F24Si10Ge9 was input. In addition, the thin film density obtained in (Measurement of Density of Upper Layer Film) described above was input in the column of Density. In addition, 0.02 microns was input in the column of Thickness. In addition, 12 to 14 nm was input as Wavelength Range. For other inputs, FIG. 5is referred to.
(3) The button of Submit Request was pressed to output the graph. Then, when the value of Transmission at a wavelength of 13.5 nm was denoted by T, a value of (1−T)×100 was used as the EUV radiation absorption amount (%).

The results of calculation of the element composition by the XPS, the thin film density by the XRR, and the EUV radiation absorption amount for the upper layer films (simulation films) obtained in each of Examples and Comparative Examples described above are shown in the table below.

TABLE 2

| | Element | Thin film | EUV radiation |
|---|---|---|---|
| | composition | density | absorption |
| | [at %] | [g/cm³] | amount [%] |
| Composition 1 | C: 22, O: 35, F: 24, | 2.03 | 22.3 |
| | Si: 10, Ge: 9 | | |
| Composition 2 | C: 34, O: 20, F: 34, | 1.99 | 22.2 |
| | Si: 6, Ge: 6 | | |
| Composition 3 | C: 42, O: 21, F: 28, | 1.55 | 15.0 |
| (Comparative | Si: 19 | | |
| Example) | | | |
| Composition 4 | C: 41, O: 21, F: 23, | 1.82 | 20.2 |
| | Ge: 15 | | |
| Composition 5 | C: 42, O: 19, F: 31 | 2.11 | 17.5 |
| | Si: 2, W: 6 | | |
| Composition 6 | C: 42, O: 20, F: 24, | 1.78 | 20.1 |
| | Ge: 14 | | |
| Composition 7 | C: 50, O: 17, F: 33 | 1.01 | 13.5 |
| (Comparative | | | |
| Example) | | | |

As shown in the above table, Examples have higher radiation absorption and higher secondary electron generation efficiency than Comparative Examples, and an improvement in sensitivity can be expected.

### Sensitivity Evaluation by Electron Beam Irradiation

Hereinafter, the sensitivity was evaluated by actually irradiating the laminate with an electron beam and performing a development treatment.

The measurement of the film thickness in the following was performed with an ellipsometer produced by HORIBA, Ltd.

### (Preparation of Laminate 1)

### Formation of Photoresist Film

A positive electron beam resist composition ZEP-520A produced by Zeon Corporation was filtered through a filter having a pore size of 0.22 μm.

The filtered composition was applied to a silicon wafer having a diameter of 4 inches and a thickness of 525 μm, produced by SUMCO CORPORATION, by spin coating at a rotation speed of 2,000 rpm.

Then, the silicon wafer was heated on a hot plate at 150° C. for 1 minute to obtain a photoresist film having a film thickness of 20 nm.

### Formation of Resist Upper Layer Film

A solution obtained by diluting resin composition 1 for forming an upper layer film described above with MIBC to 1% by mass was filtered through a filter having a pore size of 0.22 μm to obtain a coating solution. The coating solution was applied to the above-described photoresist film by spin coating at a rotation speed of 3,000 rpm. Thereafter, the silicon wafer was heated using a hot plate at 100° C. for 3 minutes.

In the above-described manner, a laminate 1 in which the photoresist film and the resist upper layer film having a film thickness of 5 nm were laminated on the silicon wafer in this order was obtained.

### (Preparation of Laminate 2)

### Formation of Photoresist Film

A laminate 2 was prepared in the same manner as in the preparation of laminate 1.

### Formation of Resist Upper Layer Film

A solution obtained by diluting the resin composition 3 for forming an upper layer film described above with MIBC to 1% by mass was filtered through a filter having a pore size of 0.22 μm to obtain a coating solution. The coating solution was applied to the above-described photoresist film by spin coating at a rotation speed of 3,000 rpm. Thereafter, the silicon wafer was heated using a hot plate at 100° C. for 3 minutes.

In the above-described manner, the laminate 2 in which the photoresist film and the resist upper layer film having a film thickness of 5 nm were laminated on the silicon wafer in this order was obtained.

### (Evaluation of Improvement in Sensitivity: Electron Beam Irradiation Test)

The surfaces of the resist upper layer films of the laminates 1 and 2 were irradiated with an electron beam using ELS-G100-SP (100 keV) produced by Elionix Inc. Specifically, the electron beam was applied while changing the irradiation position to provide an irradiation region in which the irradiation amount of the electron beam varied from 5 μC/cm² to 250 μC/cm² in one laminate with increments of 5 μC/cm².

After the irradiation was completed, the laminate was immersed in butyl acetate for 30 seconds and subjected to development.

The film thickness of the laminated film corresponding to the irradiation area after the development was measured with DektaK-XT-A produced by Bruker Corporation. Then, the irradiation amount at which the film thickness of the photoresist film was reduced to zero was defined as a required irradiation amount Eₜₕ.

The results are shown in Table 3.

TABLE 3

| | | Resin | |
|---|---|---|---|
| | | composition for | |
| | | forming upper | Eₜₕ |
| | Laminate | layer film | [μC/cm²] |
| Example | 1 | 1 | 65.8 |
| Comparative | 2 | 3 | 80.3 |
| Example | | | |

As shown in Table 3, Eₜₕ in the laminate 1 of Example in which the resist upper layer film contained a predetermined amount of the sensitizing element was smaller than Eₜₕ in the laminate 2 of Comparative Example in which the resist upper layer film did not contain the sensitizing element. That is, Example had higher sensitivity than Comparative Example. This result indicates that the secondary electrons generated in the resist upper layer film by the irradiation with the electron beam are propagated to the photoresist film and contribute to an improvement in sensitivity.

There is a correlation between the resist sensitivity in electron beam irradiation and the resist sensitivity in EUV exposure (for example, refer to Radiation Chemistry No. 107 (2019)). Therefore, by forming the resist upper layer film using the resin composition for forming an upper layer film containing a predetermined amount or more of the sensitizing element as in the present embodiment, it can be expected that the sensitivity can be improved during EUV exposure without improving the photoresist itself.

### Consideration on Sensitivity Improving Effect

In Table 3, it can be said that Example and Comparative Example correspond to the composition 1 and the composition 3 (Comparative Example) in Table 2.

In Table 2, the EUV radiation absorption amount, which is an index of improvement in sensitivity, is 22.3% for the composition 1 and 15% for the composition 3. Therefore, from Table 2, it can be said that the sensitivity when using the composition 1 is improved by 22.3%-15% =7.3% compared to the sensitivity when using the composition 3.

On the other hand, from the numerical values in Table 3, it can be said that the degree of improvement in sensitivity of Example with respect to Comparative Example is {(80.3−65.8)/80.3}×100=18%.

The EUV radiation absorption amount in Table 2 is a value based on calculation, and the sensitivity in Table 3 is an actually measured value. Further, the degree of improvement in sensitivity derived from Table 3 is greater than the degree of improvement in sensitivity derived from Table 2, which indicates the unexpected and remarkable effect of the present embodiment.

This application claims priority based on Japanese Patent Application No. 2022-095902 filed on Jun. 14, 2022, the entire disclosure of which is incorporated herein.

### REFERENCE SIGNS LIST

10 substrate
20 photoresist film
30 resist upper layer film
50 photomask
60 actinic ray
20B pattern

1. A resin composition for forming a resist upper layer film, the resin composition comprising:
one or more sensitizing elements selected from the group consisting of Ge, Mo, Hf, Zr, Ta, W, Cr, Co, Fe, Pt, Sn, and Sb,
wherein an amount of the sensitizing element in non-volatile components is 5 at % or more.

2. The resin composition for forming a resist upper layer film according to claim 1, further comprising:
a resin containing the sensitizing element.

3. The resin composition for forming a resist upper layer film according to claim 2,
wherein the resin includes a polysiloxane-based resin containing the sensitizing element.

4. The resin composition for forming a resist upper layer film according to claim 2,
wherein the resin includes a polysiloxane-based resin in which a part of Si atoms of polysiloxane is replaced by the sensitizing element.

5. The resin composition for forming a resist upper layer film according to claim 2,
wherein the resin has an alkali-soluble group.

6. The resin composition for forming a resist upper layer film according to claim 1, further comprising:
a resin; and
an additive component containing the sensitizing element as a component separate from the resin.

7. The resin composition for forming a resist upper layer film according to claim 6,
wherein the resin is a (meth) acrylic resin.

8. The resin composition for forming a resist upper layer film according to claim 6,
wherein the resin has an alkali-soluble group.

9. The resin composition for forming a resist upper layer film according to claim 6,
wherein the additive component includes one or more selected from the group consisting of tetraethoxygermanium, silicotungstic acid, and bis [2-carboxyethylgermanium (IV)] sesquioxide.

10. The resin composition for forming a resist upper layer film according to claim 1,
wherein the sensitizing element includes one or more selected from the group consisting of Ge, Mo, and W.

11. The resin composition for forming a resist upper layer film according to claim 1, further comprising:
an alcohol-based solvent.

12. The resin composition for forming a resist upper layer film according to claim 1,
wherein the resin composition is non-photosensitive.

13. The resin composition for forming a resist upper layer film according to claim 1,
wherein the resin composition is used in an EUV lithography process.

14. A method for forming a pattern, comprising:
a photoresist film forming step of forming a photoresist film over a substrate;
a resist upper layer film forming step of forming a resist upper layer film over the photoresist film using the resin composition for forming a resist upper layer film according to claim 1;
an exposing step of exposing the photoresist film and the resist upper layer film; and
a developing step of removing at least a part of the photoresist film using a developer.

15. The method for forming a pattern according to claim 14,
wherein the resist upper layer film is removed in the developing step.

16. The method for forming a pattern according to claim 14, further comprising:
a resist upper layer film removing step of removing the resist upper layer film, between the exposing step and the developing step.

17. The method for forming a pattern according to claim 14,
wherein the exposing step is performed using EUV light.

18. The method for forming a pattern according to claim 14,
wherein a thickness of the photoresist film is 30 nm or less.

19. A method for producing an electronic device, the method comprising:
the method for forming a pattern according to claim 14.
